(19) United States
(12) Patent Application Publication
(10) Pub. No.: US 2006/0086310 A1
(43) Pub. Date: Apr. 27, 2006

(54) Production of high grade silicon, reactor, particle recapture tower and use of the aforementioned

(76) Inventor: Per Kristian Egeberg, Kristiansand (NO)

Correspondence Address: SEYFARTH SHAW LLP, 55 E. MONROE STREET, SUITE 4200, CHICAGO, IL, 60603-5803, US

(21) Appl. No.: 10/522,956

(22) PCT Filed: Jul. 30, 2003
(86) PCT No.: PCT/NO03/00263

§ 371 Date: Oct. 19, 2005

(30) Foreign Application Priority Data
Jul. 31, 2002 (NO) 20023647
Jul. 15, 2003 (NO) 20033207

(51) Int. Cl. C30B 11/00

(52) U.S. Cl. 117/11

(57) ABSTRACT

Solar Grade Silicon is produced by decomposition of a silicon precursor, preferably trichlorosilane, in the presence of an excess of hydrogen gas, where the reactant are introduced in a reaction chamber whose lower portion is held at a temperature above the melting point of silicon and whose upper portion is held at ambient temperatures. The method is distinguished by the introduction of trichlorosilane through a feed pipe which is arranged coaxially inside an outer pipe for introducing hydrogen gas that functions as a cooling medium for the introduced fluid trichlorosilane. The silicon formed is collected in the lower portion of the reactor and removed through an outlet. Excess hydrogen and hydrogen chloride is withdrawn through an outlet and can, after purification, be used as reactants in the essentially closed system for the production of pure silicon from low grade silicon. Silicon particles in the off gases can be separated, melted and recycled using a particle recapture tower.

### FIELD OF THE INVENTION

The present invention relates to the production of pure solar grade silicon, by the reduction of a silicon precursor, particularly trichlorosilane, with hydrogen, together with an apparatus for the practice of the method. In particularly, the invention relates to an integrated process for the preparation of solar grade silicon from lower grade silicon. The present invention also relates to the separation, melting and recycling of particles from off-gases from the preparation of silicon, particularly silicon particles from the gas phase.

### BACKGROUND OF THE INVENTION

The preparation of elementary silicon by reduction of trichlorsilane is known in the art. U.S. Pat. No. 4,547,258 describes the preparation of liquid silicon by passing a mixture of trichlorsilane and hydrogen into a column containing silicon nitride particles that have bean heated to above the melting point of silicon. The silicon formed flows down through the column under which it is collected as a melt, which can be further purified by crystallization. Hydrogen chloride that is formed by the reduction of trichlorsilane is removed from the top of the column.

U.S. Pat. No. 4,668,493 presents a method for the preparation of silicon by thermal reaction of silane (SiH₄) by thermal decomposition of silane, introducing the feed gas containing silane and hydrogen into a reaction chamber where the temperature is held above the melting point of silicon. The formed silicon is collected in the reactor bottom for subsequent removal and additional purification, if necessary. Although the reactor described in U.S. Pat. No. 4,668,493 is particularly suitable for thermal reaction of silane it is also mentioned that it can be used for tetrachlorosilane or trichlorsilane as well.

U.S. Pat. No. 4,102,764 describes a method for the production of pure silicon by introducing a silicon precursor such as tetrachlorosilane, with hydrogen, into a reaction chamber heated by an electric arc. The use of this reaction chamber is shown incorporated into an integrated process for the manufacture of silicon, for example from silicon dioxide reduced with carbon, where the formed impure silicon is converted with hydrogen chloride. After purification, the formed chlorosilane which was introduced into the aforementioned electric arc heated reaction chamber, from which liquid silicon is removed, and unconverted chlorosilanes, hydrogen and hydrogen chloride are sent to a discharge separator, from which the chlorosilanes are brought back to the electric arc reactor for additional conversion, and separated hydrogen chloride after recharging with hydrogen chloride is used for conversion of silicon to silanes.

U.S. Pat. No. 4,176,166 describes a method for the production of pure silicon by continuous mixing of hydrogen and at least one halogenated silane in gaseous state directly over a pool of liquid silicon. The gases are introduced in heated tubes and silicon formed by the reaction is collected in the pool of liquid silicon and removed for casting. U.S. Pat. No 4,176,166 has a design that does not allow for a temperature gradient to be established, which will lead to a greater formation of bi-products in the hot reaction zone. Since the method also shows injection of hydrogen through an inner tube, premature decomposition is not taken into consideration, and the possibility for a cooling effect from the injection of trichlorsilane though an inner capillary tube, as described in the present invention, is lost. In addition U.S. Pat. No. 4,176,166 lacks a system for maintaining the molten silicon at a constant level.

One or more disadvantages of the prior art for methods for producing liquid silicon by reduction of a halogenated silane with hydrogen are:
1. The premature decomposition of the silicon precursor and the fouling of feed lines.
2. The plugging of exit lines with particles formed in the reactor.
3. Contamination.

The above mentioned disadvantages are partially of completely eliminated with the method of the present invention.

It is known from scientific literature and related patents that decomposition of silanes in free space reactors can lead to the formation of microscopic silicon particles that can be carried out of the reactor with the off gas. Many industrial processes require removal of particles from the off gas. This problem is usually solved by separation of the particles in a cleansing process down stream from the reactor. U.S. Pat. No. 6,176,901 shows the capture of silicon particles formed during the Czochralski process with the use of adhesion to cooled surfaces down stream from the crystal pulling operation. In some fluidized bed operations (e.g. U.S. Pat. No. 4,992,085) gravity based particle collectors and recycling of separated particles are used. All the considered methods are based on processes where the particles are captured on a surface and collected or recycled in particle form. The disadvantages of several of these methods is reduces efficiency due to electrostatic repulsion between the surface and the particle, altered flow characteristics when the collector is being filled, altered filtration properties when the filter pores are plugged, limited filter capacity, complicated systems for transportation of collected dust, and more. In applications where the particles represent a resource, and the purity of the particles is critical, the above mentioned methods can also lead to contamination of the particles. The above mentioned disadvantages are partially or completely eliminated with the use of the cleaning method of the present invention.

### SUMMARY OF THE INVENTION

Pure silicon is produced by reduction of a silicon precursor, preferably trichlorosilane, with hydrogen in a reactor according to the present invention, by introducing is a silicon precursor to the reactor through a tube which is arranged coaxially with an outer tube through which hydrogen gas is fed. The lower part of the reactor is held at the melting point of silicon, about 1410° C. and the upper part is held at ambient temperature. Liquid silicon is prepared according to the reaction:
SiHCl₃(g)+H₂(g)=>Si(l)+3HCl(g)

The invention also relates to a reactor for carrying out the method, along with the use of this in an integrated, approximately closed system for the production of high grade silicon from a silicon raw material.

The invention also relates to an off gas cleaning system in the form of a particle recapture tower that is placed inside a secondary decomposition chamber, as decomposition of silanes in free space reactors can lead to the formation of microscopic silicon particles that can be carried out of the reactor with the off gas.

### BRIEF DESCRIPTION OF THE DRAWINGS

FIG. 1 shows a schematic representation of a reactor for use with the method of the present invention.

FIG. 2 shows a schematic representation of an integrated system for the production of high grade silicon.

FIG. 3A shows the primary decomposition chamber with a particle recapture tower and a secondary decomposition chamber on the off gas outlet.

FIG. 3B shows a cross sectional view of the particle recapture tower as seen from the side and from the top.

FIG. 3C shows the injection system.

FIG. 4 shows results of analysis of the reactor gas after steady state has been reached as compared to a signal without any form for conversion (100% SiHCl₃).

FIGS. 6A, 6B and 6C show the results of the analysis of the reactor gas when using varying H₂:SiHCl₃ mixtures.

### DETAILED DESCRIPTION OF THE INVENTION

The object of the method is to produce solar grade silicon (SOG) by decomposition of a silicon precursor, for example SiHCl₃ (g), directly to liquid silicon at about 1420° C. in the presence of a large excess of hydrogen, as shown in reaction (1).
SiHCl₃(g)+H₂(g)=>Si(l)+3HCl(g) (1)

Decomposition Reactor

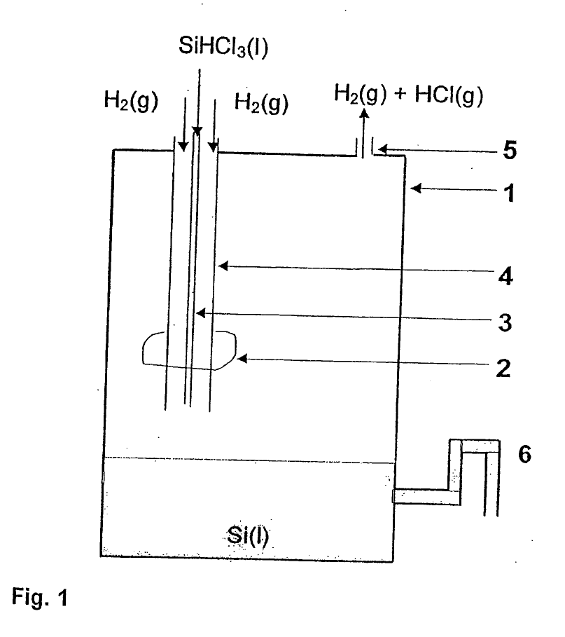

FIG. 1 gives a schematic representation of a reactor for the practice of the present invention. The reactor (1) includes a piping system (2) consisting of a pipe (3) arranged coaxially with an outer pipe (4) through which hydrogen gas is introduced, the silicon precursor (e.g. liquid trichlorosilane) is introduced through the coaxially arranged pipe (3) and the resulting hydrogen chloride gas and excess hydrogen is removed through outlet (5). The formed product, that is liquid silicon, exits through an overflow pipe (6). The inside of the reactor is constructed according to the state of the art with an inert material such as silicon nitride, silicon carbide or quarts, whereby contamination of the formed silicon is reduces. The following advantages arise from the use of the reaction chamber of the present invention:
1. Decomposition occurs in a temperature gradient which enables secondary reactions to have an increased rate of conversion.
2. Premature decomposition is prevented by
   a. The gases being introduced in separate tubes;
   b. The hydrogen is used to cool the inlet tube for the silicon precursor (for example trichlorosilane);
   c. The silicon precursor is injected as a fluid through a capillary tube, thereby achieving a cooling effect in that A) the silicon precursor vaporized upon passing through the tube, and B) by the significant pressure drop and expansion that takes place when the silicon precursor exits the vapour tube;
   d. The distance from the surface of the melt can be increased as the gases have such a high exit velocity that they are “shot” down toward the surface of the melt. Therefore the injection tube can be place high in the decomposition chamber where the temperature is lower:
   e. Pre-heating the reactants is not necessary.
3. The exit pipe for the off gases is positioned as far as possible from the decomposition zone where particles are formed and the lower exit temperature prevents continued decomposition into the off gas system.
4. The level of liquid silicon is regulated by a constant level in the outlet pipe.

Integrated System

An essentially closed process without waste products is achieved by integrating production of SiHCl₃ (g) in the process, as shown in reaction (2).
Low Grade Si+Energy=High Grade Si (2)

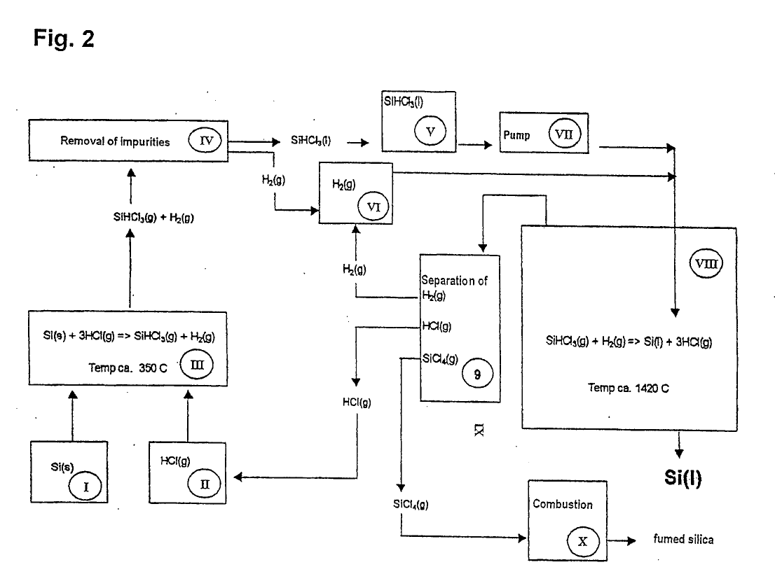

FIG. 2 provides a schematic representation of an integrated system for the production of high grade silicon. IT is the decomposition reactor described above which makes this process possible. SiHCl₃ (g) is produced in a fluidized bed reactor (III) by a reaction between low grade silicon (I) and HCl (II):
Si(s)+3HCl(g)=>SiHCl₃(g)+H₂(g) (3)

It is possible to achieve up to a 99% yield of trichlorosilane through careful control of the reaction conditions.

By-products from reaction (3) and hydrogen are separated from SiHCl₃ in a cleaning step (IV) based on distillation, alternatively partial condensation. After separation the condensed trichlorosilane and hydrogen are lead to separate storage tanks (V and VI). Trichlorosilane is injected in the decomposition chamber (VIII) in liquid form (V) by a pump (VII). High grade molten silicon is continuously drawn from the reactor. Hydrogen (VI) is injected separately into the decomposition chamber. After the reaction hydrogen and hydrochloric acid are separated (IX) by membrane technology after the removal of tetrachlorosilane and other by-products by condensation (IX). Hydrogen and hydrochloric acid vapour is recycled to the storage tanks (VI) and (II), respectively. Tetrachlorosilane and other possible SiₓH_{y}Cl_{z} compounds are lead to an incinerator (X) for the production of microsilica (SiO₂). One aspect of the invention relates to the production of high grade silicon in this essentially closed process.

Particle Recapture Tower

Decomposition of silanes in free space reactor can lead to the formation of microscopic silicon particles, or fines, which can be carried out of the reactor with the off gas. According to the present invention, off gases containing particles (for example silicon particles) are passed into a particle recapture tower where the particles are collected, partly by collision with the surface of the particle recapture tower and partly by collision with the downward flow of molten silicon, whereby the particles melt and flow back to the pool of molten silicon.

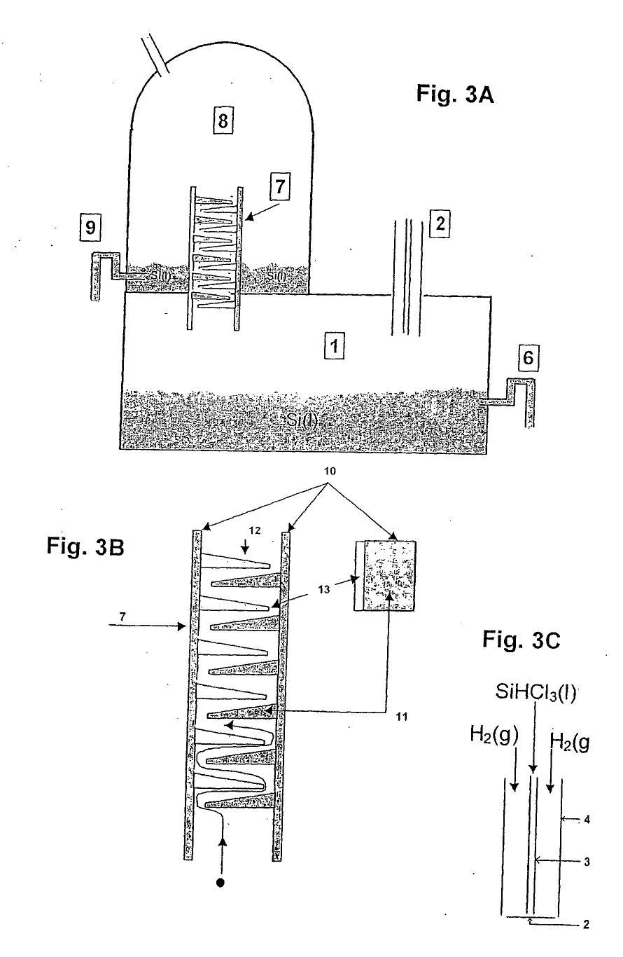

The recapture is achieved when the decomposition chamber, shown in FIG. 3A, consists of the previously described injection system (2 and FIG. 3C), a primary decomposition chamber (1), a particle recapture tower (7 and FIG. 3B), a secondary decomposition chamber (8) and systems for removing the liquid silicon (9).

The fluid trichlorosilane and hydrogen is injected as described via the coaxial injection system, shown in FIG. 3C, in the primary decomposition chamber (1) which is held at a temperature over the melting point of silicon. Here the decomposition occurs in the presence of a large excess of hydrogen.

Particles that are not entrained in the melt in the primary decomposition chamber (1) are transported with the off gases into the particle recapture tower (7 and FIG. 3B).

FIG. 3B gives a graphic presentation of a particle recapture tower for use with the method of present invention. The particle recapture tower (7) includes a channel (10) shown here with a square cross section, but can also have another geometry (12) (for example circular) and sloping partitions (11), designed so as to create a gap (13) between the partition and the channel wall (10). The partitions (11) are placed so that the gap (13) alternates from side to side. The distance between the partitions, as well as the size of the gap and the angle of the upper side of the partition, are designed to accommodate the flow rate, particle concentration and the viscosity of the melt, and can vary along the channel. The channel walls and the partitions are held at a temperature over the melting point of the particles that are to be captured.

Capture of the particles is achieved by two methods. ¹⁾When the gas stream is forced to change direction due to the partitions, the direction of particles changes to a lesser degree because the have a higher density than the gas. The particles will therefore collide with the channel wall and the partitions. The channel wall and the partitions are held at a temperature above the melting point of the particles. Upon collision the particles will be captured in the film of molten material (for example molten silicon) that forms on the surface of the channel wall and partitions, and the particles melt and contribute to the build up of the film of molten material. ²⁾When the film of molten material reaches a critical thickness, which is dependent on the temperature and angle of the partitions, the material will begin to drain downward. A “rain” of molten material is formed when the material drains vertically from partition to partition and from the lowest partition to the melt beneath. This “rain” of moltenmaterial has the opposite direction of flow to the particles and will also contribute to the capture of particles upon collision.

Secondary Decomposition Chamber

As indicated above, it is desirable to establish a temperature gradient in the decomposition chamber so that any by-products (e.g. SiCl₂) from the primary reaction SiHCl₃+H₂=>Si+3HCl can be transformed to silicon by secondary reactions at temperatures under the melting point of silicon. In the secondary decomposition chamber (8) this temperature gradient in established in such a way that the entire particle recapture tower is held at a temperature above the melting point of silicon while the top of,the reactor is cooled. Consequently silicon particles formed in the secondary reactions in the cooled portion of the secondary decompositions chamber fall into the melt at the bottom of the chamber.

Removal System

Both the primary and secondary decomposition chamber is equipped with mechanisms for removal of liquid silicon (5 in FIG. 3A). The removal system is designed to hold the molten silicon inside the reaction chamber at a constant level.

Experimental Results

Production of pure silicon with the use of a reactor according to the present invention is described in the following. Trichlorosilane was used as a source for the production of silicon, but it is obvious that any other silicon precursor may be used, such as silane, tetrachlorosilane, and other halogenated silanes. Trichlorosilane is the preferred base material for the production of pure silicon, as trichlorosilane is inexpensive and easily produced.

Preliminary experiments were conducts with a flow through reactor where trichlorosilane was passed through a reactor with varying amounts of hydrogen added. In such a flow through reactor, the excess hydrogen will lead to greater conversion of trichlorosilane to silicon. The use of a reactor with a large excess of hydrogen, such as that described in U.S. Pat. No. 4,176,166 will, however, lead to the formation of chlorosilane gas. According to the present method and using the decomposition reactor of the present invention, with a large temperature gradient between the surface of the molten silicon and the upper portion of the reactor, the silicon chloride will react with the excess hydrogen in the cold temperature zone according to the following equation:
SiCl₂(g)+H₂(g)=>Si(s)+2HCl(g)

The solid silicon thus formed will fall into the molten silicon. In this manner loss of silicon in the form of SiCl₂ is avoided and the yield is increased. Preliminary experiments have show, by GC analysis of exit gasses, a yield of Si of about 80% with a H₂:SiHiCl₃ ratio in the injection gas of 6:1. The exit gas in this experiment contained only about 2% SiCl₄ which is assumed to have formed by the reaction:
2SiHCl₃=>Si+SiCl₄+2HCl

### EXAMPLE 1

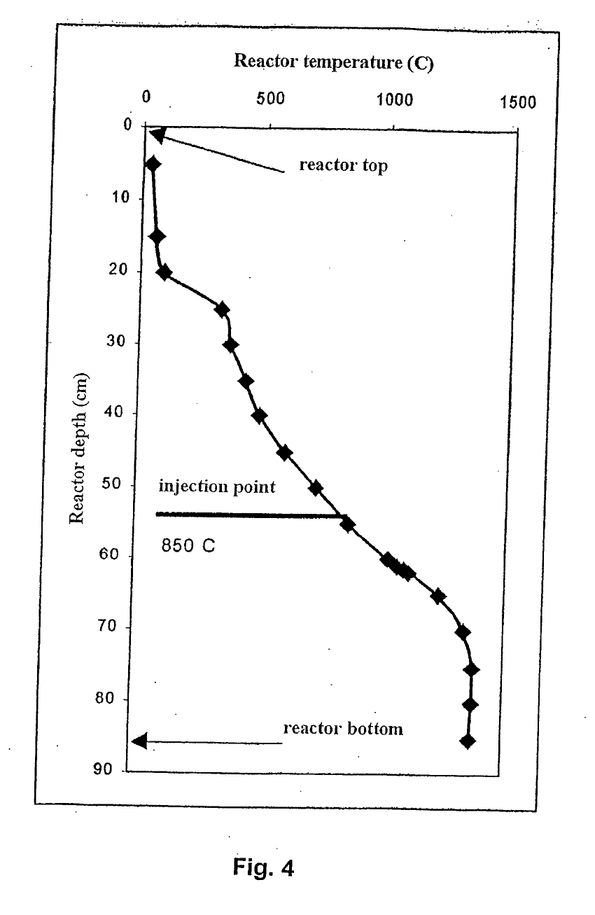

A vertical reactor was utilized with a closed bottom, a height of 85 cm, an inner diameter of 4.5 cm, and an established temperature gradient as depicted in the graph in FIG. 4.

The reactor was supplied with a feed system consisting of an inner steel pipe with a diameter of 0.25 mm, place inside an outer steel pipe with an inner diameter of 2.18 mm. SiHCl₃ was introduced using a high pressure pump (0.2 ml/min) equivalent to about 50 ml/min gas at STP. Hydrogen gas was introduced through the outer pipe at a rate of 50 ml/min. The lowest theoretical H₂:SiHCl₃ ratio possible was used, in order to indicate the lowest possible cooling is effect from the hydrogen gas introduced. The purpose of this experiment was therefore not to achieve the highest possible conversion of introduced trichlorosilane.

The most significant result from this experiment which ran for three hours, was that there was no signs of fouling in the feed system. As expected, a lover conversion of SiHCl₃ was observed, which can be ascribed to the low H₂:SiHCl₃ ration as well as the reactor dimensions where the inner diameter of the reactor was relatively small compared to the height of the reactor, with the result that a lesser portion of the injection gas reached down into the high temperature zone. The latter condition is not considered to be a significant objection, as it can easily be avoided by choosing a different dimensional relationship between the injection system and the reactor dimensions.

The results obtained are shown in the graph of FIG. 5 which depicts the results of the analysis of the reactor gas after steady state has been reached and which compares this with what the signal would have been without any conversion (100% SiHC1₃). In this experiment about 70% conversion of SiHCl₃ was achieved and about 26% was recycled as SiCl₄ in the off gas.

It is obvious that a higher conversion would have been achieved with the use of an excess of hydrogen in relation to the introduced stoichiometric amount. The experimental reactor used did not have an outlet for the liquid silicon which was deposited on the sides and bottom of the lower, warmer portion of the reactor.

### EXAMPLE 2

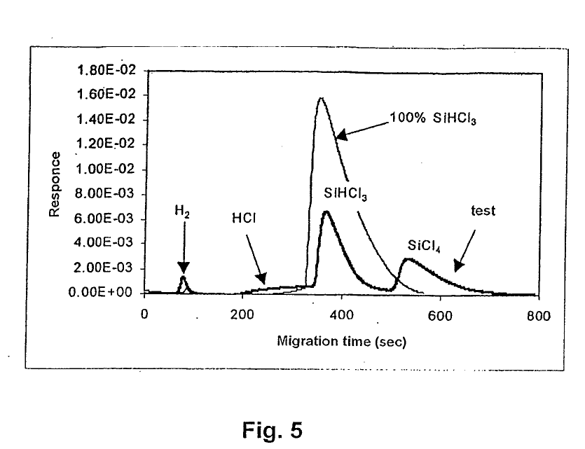

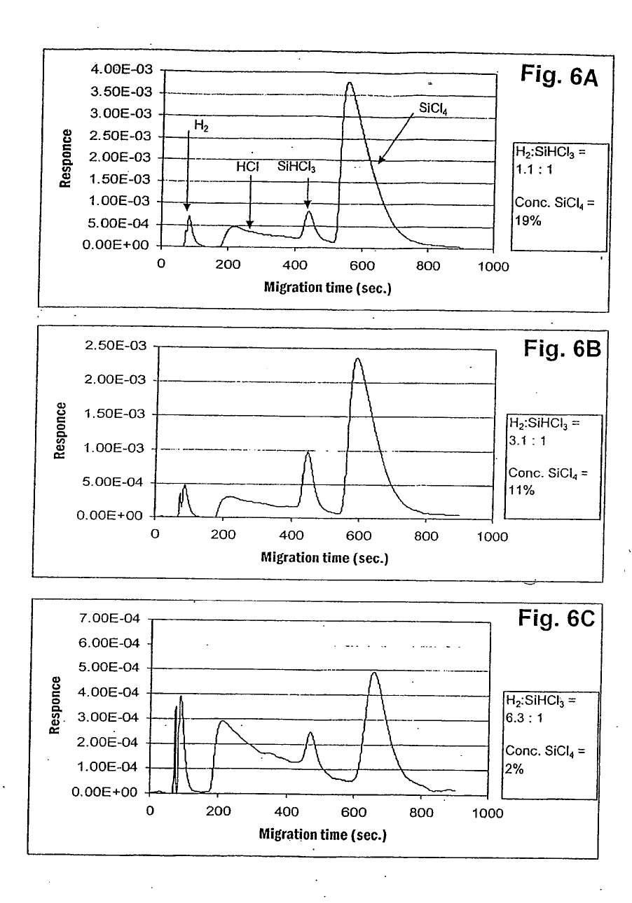

In order to suppress the formation of tetrachlorosilane (SiCl₄), it is necessary to use an excess of hydrogen. The effect of the H₂:SiHCl₃ ration was investigated in a series of experiments with the ratios 1.1:1, 3.1:1 and 6.3:1. In this series, the concentration of SiCl₄ in the off gas decreases from 19% to 2%. The results are presented in FIG. 6.

1. A method for producing Solar Grade Silicon by thermal decomposition of a silicon precursor in the presence of an excess of hydrogen by separately introducing hydrogen gas and the silicon precursor in a vertically oriented reaction chamber in which the lower portion holds a pool of molten silicon, the surface of which the reactants are directed toward and react during the formation of essentially elementary silicon and hydrogen chloride, off gases and by—products formed are withdrawn from the upper portion of the column; silicon formed is withdrawn from the lower portion of the reactor, characterized in that the fluid silicon precursor in introduced at ambient temperatures through a pipe arranged coaxially in a feed pipe for hydrogen gas, where the hydrogen gas functions as a cooling medium for the introduced silicon precursor, in that a steep temperature gradient is held within the reactor, and that the reactants are conducted at great speed toward the surface of the molten silicon by rapid expansion of the silicon precursor and hydrogen gas, and brought to react in the lower warm portion of the reactor, in that any formed silicon chloride reacts with the excess hydrogen in the upper portion of the reactor and falls as particulate solid silicon.

2. The method according to claim 1 wherein the silicon precursor is trichlorosilane, silane, tetrachlorosilane, or other halogenated silanes, preferably trichlorosilane.

3. The method according to claim 1, wherein the lower portion of the reactor is held at a temperature above the melting point of silicon, 1410° C., and the cold upper portion is held at a temperature under 400° C.

4. The method according to claim 1, characterized in that wherein the level of molten silicon in the reactor is held constant by a constant level system for continuous removal.

5. A reactor for the practice of the method according to tee claim 1 comprising an elongated container with an inert lining, where the container is equipped with an injection system for a silicon precursor, preferably trichlorosilane, and hydrogen, and an outlet for unconverted hydrogen HCl and any by-products, comprising a constant level outlet system for produced, liquid silicon, that the feed system comprises an outer pipe for introducing hydrogen gas and a pipe arranged coaxially with pipe for the introduction of fluid silicon precursor, and where the height of the reactor is sufficient to establish the necessary steep temperature gradient.

6. Reactor according to claim 5, wherein the temperature in the lower portion of the reactor is held at a temperature above the melting point of silicon, 1410° C., and the cold upper portion is held at a temperature under 400° C.

7. The method according to of claim 1 for the production of Solar Grade Silicon in an integrated, essentially closed process comprising reacting low grade silicon with hydrogen chloride gas during the formation of trichlorosilane which is introduced into a reactor wherein said reactor comprises an elongated container with an inert lining, where the container is equipped with an injection system for a silicon precursor preferably trichlorosilane, and hydrogen, and an outlet for unconverted hydrogen HCl and any by-products characterized by a constant level outlet system for produced, liquid silicon, that the feed system comprises an outer pipe for introducing hydrogen gas and a pipe arranged coaxially with pipe for the introduction of fluid silicon precursor, and where the height of the reactor is sufficient to establish the necessary steep temperature gradient, after which unconverted hydrogen and hydrogen chloride are separated and hydrogen chloride gas is used for the conversion of additional low grade silicon and the hydrogen gas is introduced as a reactant in the process.

8. A method for the removal of particles from off gas by placing a particle recapture tower on the off gas outlet from a reactor or kiln, wherein both the particle recapture tower and the reactor (kiln) are held at a temperature above the melting point of the particles, and which leads to the capture and melting of the particles, and their flowing back to the molten material.

9. The method according to claim 8, wherein the particle recapture tower has a channel with alternating partitions which result in an undulating flow pattern for the particle carrying gas phase.

10. The method according to claim 8, wherein the particles, due to the undulating flow pattern, are captured in the molten phase on the channel walls and partitions.

11. The method according to claim 8, wherein the molten phase, due to the sloping upper side of the partitions, flow vertically downward.

12. A particle recapture tower for the practice of the method according to claim 8, wherein it comprises a channel with partitions with downward sloping geometry, designed so that an opening is formed between the partition and the channel wall, where the partitions alternate from side to side.

13. The particle recapture tower according to claim 12, wherein the cross section of the channel is preferably square.

14. The particle recapture tower according to claim 12, wherein the channel walls and the partitions are held at a temperature above the melting point of the particles to be captured.

15. The particle recapture tower according to claim 12 wherein the particle recapture tower is situated in a secondary reaction chamber in which a steep temperature gradient is held between the upper portion of the reaction chamber and the particle recapture tower.

16. The particle recapture tower according to claim 12 for the production of Solar Grade Silicon by thermal decomposition of a silicon precursor in the presence of an excess of hydrogen by separately introducing hydrogen gas and the silicon precursor in a vertically oriented reaction chamber in which the lower portion holds a pool of molten silicon, the surface of which the reactants are directed toward and react during the formation of essentially elementary silicon and hydrogen chloride, off gases and by—products formed are withdrawn from the upper portion of the column; silicon formed is withdrawn from the lower portion of the reactor, characterized in that the fluid silicon precursor in introduced at ambient temperatures through a pipe arranged coaxially in a feed pipe for hydrogen gas, where the hydrogen gas functions as a cooling medium for the introduced silicon precursor, in that a steep temperature gradient is held within the reactor, and that the reactants are conducted at great speed toward the surface of the molten silicon by rapid expansion of the silicon precursor and hydrogen gas, and brought to react in the lower warm portion of the reactor, in that any formed silicon chloride reacts with the excess hydrogen in the upper portion of the reactor and falls as particulate solid silicon on the off gases from the primary decomposition chamber.
